(19) United States
(12) Patent Application Publication
(10) Pub. No.: US 2018/0375538 A1
(43) Pub. Date: Dec. 27, 2018

(54) APPARATUS FOR PROVIDING A CONTROL SIGNAL FOR A VARIABLE IMPEDANCE MATCHING CIRCUIT AND A METHOD THEREOF

(71) Applicant: Intel Corporation, Santa Clara, CA (US)

(72) Inventors: Andrei Panioukov, Moscow (RU); Pablo Herrero, Munich (DE)

(21) Appl. No.: 16/119,207

(22) Filed: Aug. 31, 2018

Related U.S. Application Data
(62) Division of application No. 14/865,514, filed on Sep. 25, 2015.

(30) Foreign Application Priority Data
Dec. 19, 2014 (DE) 10 2014 119 259.1

(51) Int. Cl. H04B 1/04; H03H 7/40; H04B 17/10

(52) U.S. Cl. CPC H04B 1/0458; H03H 7/40; H04B 17/102

(57) ABSTRACT

An apparatus for providing a control signal for a variable impedance matching circuit comprises a control module configured to generate a control signal for adjusting an impedance of a variable impedance matching circuit coupled to an antenna module. The control module is configured to generate the control signal based on a sensor signal received from a sensor circuit located in proximity to the antenna module. The sensor signal comprises information related to a power of an electromagnetic signal radiated by the antenna module.

### REFERENCE TO RELATED APPLICATION

This application is a divisional of U.S. application Ser. No. 14/865,514 filed on Sep. 25, 2015, which claims priority to German Application number 10 2014 119 259.1 filed on Dec. 19, 2014, the contents of which are incorporated by reference in their entirety.

### FIELD

The present disclosure relates to variable impedance matching and in particular to an apparatus for providing a control signal for a variable impedance matching circuit and a method thereof.

### BACKGROUND

Existing mobile application (e.g. smartphones and/or tablets) may have a strong dependence on internal antenna efficiency. Mismatching of an antenna may be characterized by a voltage standing wave ratio (VSWR) and phase of the antenna impedance. An antenna impedance may have an ideal VSWR=1 during perfect matching. However, in reality, during antenna mismatching, VSWR values can reach up to 11 to 13. This may lead to power drops resulting in degraded performance of the mobile devices.

### BRIEF DESCRIPTION OF THE DRAWINGS

Some examples of apparatuses and/or methods will be described in the following by way of example only, and with reference to the accompanying figures, in which

FIG. 1 shows a schematic illustration of an apparatus for providing control signals for a variable impedance matching circuit;

FIG. 2 shows a schematic illustration of a transmitter arrangement including an apparatus for providing control signals for a variable impedance matching circuit;

FIGS. 3A to 3D show schematic illustrations of code selection in an apparatus for providing control signals for a variable impedance matching circuit;

FIGS. 4A and 4B show examples of code looping in an apparatus for providing control signals for a variable impedance matching circuit;

FIG. 5 shows a schematic illustration of a signal generation means;

FIG. 6 shows a schematic illustration of a transmitter of transceiver including an apparatus for providing control signals for a variable impedance matching circuit or signal generation means;

FIG. 7 shows a schematic illustration of a mobile device 700 and/or a cell phone including an apparatus an apparatus for providing control signals for a variable impedance matching circuit or signal generation means;

FIG. 8 shows a flow chart of a method for providing control signals for a variable impedance matching circuit.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while examples are capable of various modifications and alternative forms, the illustrative examples in the figures will herein be described in detail. It should be understood, however, that there is no intent to limit examples to the particular forms disclosed, but on the contrary, examples are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing illustrative examples only and is not intended to be limiting. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which examples belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

In the following, various examples relate to devices (e.g. mobile device, cell phone, base station) or components (e.g. transmitter, transceiver) of devices used in wireless or mobile communications systems.

A mobile communication system may, for example, correspond to one of the mobile communication systems standardized by the 3rd Generation Partnership Project (3GPP), e.g. Global System for Mobile Communications (GSM), Enhanced Data rates for GSM Evolution (EDGE), GSM EDGE Radio Access Network (GERAN), High Speed Packet Access (HSPA), Universal Terrestrial Radio Access Network (UTRAN) or Evolved UTRAN (E-UTRAN), Long Term Evolution (LTE) or LTE-Advanced (LTE-A), or mobile communication systems with different standards, e.g. Worldwide Interoperability for Microwave Access (WIMAX) IEEE 802.16 or Wireless Local Area Network (WLAN) IEEE 802.11, generally any system based on Time Division Multiple Access (TDMA), Frequency Division Multiple Access (FDMA), Orthogonal Frequency Division Multiple Access (OFDMA), Code Division Multiple Access (CDMA), etc. The terms mobile communication system and mobile communication network may be used synonymously.

The mobile communication system may comprise a plurality of transmission points or base station transceivers operable to communicate radio signals with a mobile transceiver. In these examples, the mobile communication system may comprise mobile transceivers, relay station transceivers and base station transceivers. The relay station transceivers and base station transceivers can be composed of one or more central units and one or more remote units.

A mobile transceiver or mobile device may correspond to a smartphone, a cell phone, User Equipment (UE), a laptop, a notebook, a personal computer, a Personal Digital Assistant (PDA), a Universal Serial Bus (USB)-stick, a tablet computer, a car, etc. A mobile transceiver or terminal may also be referred to as UE or user in line with the 3GPP terminology. A base station transceiver can be located in the fixed or stationary part of the network or system. A base station transceiver may correspond to a remote radio head, a transmission point, an access point, a macro cell, a small cell, a micro cell, a pico cell, a femto cell, a metro cell etc. The term small cell may refer to any cell smaller than a macro cell, i.e. a micro cell, a pico cell, a femto cell, or a metro cell. Moreover, a femto cell is considered smaller than a pico cell, which is considered smaller than a micro cell. A base station transceiver can be a wireless interface of a wired network, which enables transmission and reception of radio signals to a UE, mobile transceiver or relay transceiver. Such a radio signal may comply with radio signals as, for example, standardized by 3GPP or, generally, in line with one or more of the above listed systems. Thus, a base station transceiver may correspond to a NodeB, an eNodeB, a BTS, an access point, etc. A relay station transceiver may correspond to an intermediate network node in the communication path between a base station transceiver and a mobile station transceiver. A relay station transceiver may forward a signal received from a mobile transceiver to a base station transceiver, signals received from the base station transceiver to the mobile station transceiver, respectively.

The mobile communication system may be cellular. The term cell refers to a coverage area of radio services provided by a transmission point, a remote unit, a remote head, a remote radio head, a base station transceiver, relay transceiver or a NodeB, an eNodeB, respectively. The terms cell and base station transceiver may be used synonymously. In some examples a cell may correspond to a sector. For example, sectors can be achieved using sector antennas, which provide a characteristic for covering an angular section around a base station transceiver or remote unit. In some examples, a base station transceiver or remote unit may, for example, operate three or six cells covering sectors of 120° (in case of three cells), 60° (in case of six cells) respectively. Likewise a relay transceiver may establish one or more cells in its coverage area. A mobile transceiver can be registered or associated with at least one cell, i.e. it can be associated to a cell such that data can be exchanged between the network and the mobile in the coverage area of the associated cell using a dedicated channel, link or connection. A mobile transceiver may hence register or be associated with a relay station or base station transceiver directly or indirectly, where an indirect registration or association may be through one or more relay transceivers.

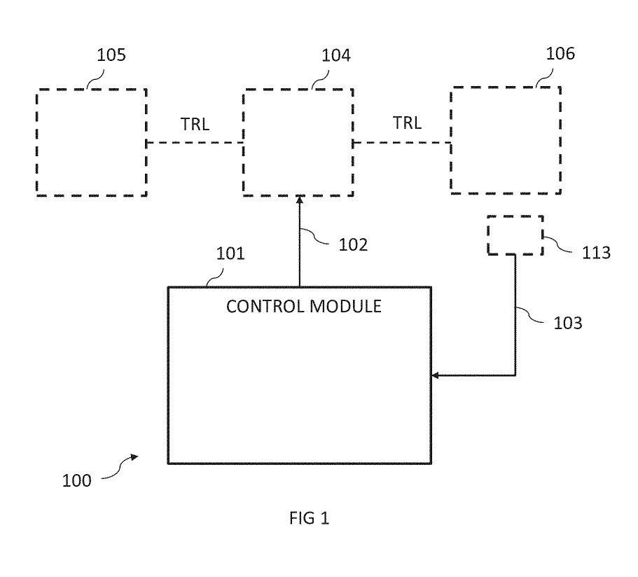

FIG. 1 shows a schematic illustration of an apparatus 100 for providing a control signal for a variable impedance matching circuit.

The apparatus 100 includes a control module 101 configured to generate a control signal 102 for adjusting an impedance of at least part of a variable impedance matching circuit coupled to an antenna module.

The control module 101 is configured to generate the control signal 102 based on a sensor signal 103 received from a sensor circuit located in proximity to the antenna module.

The sensor signal 103 includes information related to a power of an electromagnetic signal radiated by the antenna module.

Due to the adjustment of the variable impedance matching circuit based on a power actually radiated by the antenna module, the radiated power may be adjusted and/or controlled more accurately. This may lead to an improved performance of a transmitter module in which the apparatus is implemented, for example.

The apparatus 100 may include or may be implemented on a semiconductor chip or die including circuitry for providing a control signal for a variable impedance matching circuit, for example. The apparatus 100 may be configured to provide the control signal 102 for a variable impedance matching circuit of a transmitter, a receiver or a transceiver for transmitting signals (e.g. high frequency or radio frequency signals) and/or receiving signals (e.g. baseband signals), for example. The apparatus 100 may be implemented in a cell phone or a mobile device, for example.

The antenna module 106 may be an internal element (e.g. integrated with the apparatus 100) or an external element to be connected to the apparatus, for example. The antenna module 106 may be configured to radiate an energy or power based on a high frequency (radio wave) transmit signal generated by the transmitter module, for example. Occasionally, the antenna module 106 may be susceptible to external interferences (e.g. due to the position of a user's head or hand), for example. These interferences may alter an (load) impedance of the antenna module 106, resulting in an impedance mismatch between a transmission line delivering an information signal to be transmitted to the antenna module 106 and subsequently radiated by the antenna module 106, for example. While the transmission line may have a characteristic impedance (e.g. 50Ω), the antenna module 106 may fail to match the transmission line characteristic impedance resulting in standing wave reflections caused by the antenna module mismatch, for example.

The variable impedance matching circuit 104 may be configured to match an impedance between a transmission line connecting a transmission module 105 to an antenna module 106 with an antenna module load impedance. For example, the variable impedance matching circuit 104 may be configured to alter or vary an impedance between the transmission line (e.g. TRL) and the antenna module 106 so that a maximum power transfer may be carried out being the transmission line and the load (e.g. the antenna module). The variable impedance matching circuit 104 may include at least one adjustable impedance component, for example. For example, the at least one adjustable impedance component may include at least one of an adjustable capacitor circuit and an adjustable inductor circuit for varying the impedance. For example, the variable impedance matching circuit 104 may include an adjustable capacitor network or an adjustable inductor network, or a network (e.g. a T network, an L network or π network) including a mixture of capacitors and inductors, for example. By matching the impedance of the variable impedance matching circuit to the antenna module impedance, reflected (radio) waves or reflected (radio) signals may be reduced, for example. The variable impedance matching circuit 104 may include an antenna tuner circuit, for example.

The sensor circuit 113 may be located at a distance of between 5 mm to 5 cm (or e.g. 5 mm to 20 mm, or e.g. 5 mm to 10 mm) from the antenna module, for example. The sensor circuit 113 may include a field probe circuit coupled to a detector circuit. The detector circuit (e.g. a Schottky diode detector or a Schottky diode r.m.s detector) may be configured to determine a r.m.s power of the electromagnetic EM signal (or the magnetic field component of the EM signal) radiated by the antenna module 106 and sensed by the field probe (sensor) circuit 113, for example. The sensor circuit 113 may include at least one of a magnetoresistive coil, a hall sensor circuit, a capacitive circuit, an inductive circuit, and a microstrip inductor circuit, for example, or any sensor circuit capable of sensing a radio frequency electromagnetic (wave) signal radiated (through the air or atmosphere) by the antenna module. The sensor circuit 113 may further be coupled to the control module via one or more circuit components (e.g. a Schottky diode r.m.s detector, and an analog to digital ADC converter) and/or a detector interface, for example. The sensor circuit 113 may be configured to measure the power of the electromagnetic signal radiated by the antenna module with a sensing frequency, e.g. at a (sensing) time interval of between 10 μs to 30 μs. For example, the sensor circuit 113 may be configured to measure the power of the electromagnetic signal radiated by the antenna module at a time interval of between 10 μs to 0.2 s. For example, the sensor circuit may be configured to measure the power of the electromagnetic signal radiated by the antenna module repeatedly every 10 μs to 30 μs (e.g. every 20 μs), or every 10 μs to 0.2 s.

The sensor circuit 113 may be further configured to generate the sensor signal based on a measurement of the power of the electromagnetic signal. The sensor signal 103 provided by the sensor circuit to the control module and received by the control module may include information related to the power of the electromagnetic signal radiated by the antenna module. For example, the sensor signal 103 may include information related to a power of a magnetic field component of the electromagnetic signal radiated by the antenna module. Optionally, additionally or alternatively, the sensor signal may include information related to a power of an electrical field component of the radiated electromagnetic signal. For example, the sensor circuit 113 may comprise a voltage or current proportional to the power of an electrical field component of the radiated electromagnetic signal, or may comprise a value proportional to the power of an electrical field component of the radiated electromagnetic signal.

The apparatus 100 may be coupled to the transmitter module 105 or may comprise a transmitter module 105, which may include one or more circuit components (e.g. power amplifier and/or duplexer and/or a local oscillator circuits and/or mixers) configured to perform an up-conversion of a baseband signal to a high frequency (radio frequency) transmit signal to be transmitted to the antenna module.

The transmitter module 105 may be part of a transceiver module, which may further include a receiver module, which may also include one or more circuit components configured to perform a down-conversion of a high frequency signal received by the antenna module to a baseband signal.

The transmitter module 105, the control module 101 and the variable impedance matching circuit 104 may be implemented on a common semiconductor die. The sensor circuit 113 may be implemented on another (different) semiconductor die than the common semiconductor die.

The apparatus 100 may further include a coupler module. The transmitter module 105 may be coupled to the variable impedance matching circuit (e.g. the antenna tuner module) via the coupler module. The transmitter module may be coupled to the coupler module (e.g. a directivity coupler module) via at least one transmission line, e.g. a microstrip transmission line having a characteristic impedance (e.g. 50Ω), for example.

The coupler module may be configured to provide samples of the transmit signal and of a reflected portion of the transmit signal (e.g. a reflected signal), so that the transmit signal and the reflected signal may be measured individually, for example. For example, the coupler module may be configured to provide a forward feedback signal based on the high frequency transmit signal provided (or generated) by the transmitter module (to the antenna module), for example. The forward transmit wave signal may be generated by the transmitter module and transmitted via the transmission line to the antenna module, for example. The coupler module may also be configured to provide a reverse feedback signal based on a reflected portion of the high frequency transmit signal received (by the transmitter module) from the antenna module, for example. The reverse feedback signal may be based on a reflected wave signal based on impedance mismatch between the transmission line and the antenna module, for example. The coupler module may be implemented by (or as) a directional (or directivity) coupler, for example. In this way, the coupler module may be used to provide the samples of the transmit signal and the reflected signal for the measurement of a forward transmitted power and a reflected power.

The apparatus 100 may include a feedback receiver module. The coupler module may be configured to provide the forward feedback signal and the reverse feedback signal to the feedback receiver module via at least one (further) transmission line and an attenuator module (for reducing an amplitude of the forward feedback signal or the reverse feedback signal), for example.

The feedback receiver module may include at least one detector (e.g. an RF detector and/or a phase detector) configured to receive (or detect) the attenuated forward feedback signal and the attenuated reverse feedback signal. The feedback receiver module may include control circuitry, or may be coupled to a control module (e.g. control module 101), which may be configured to measure a reflection coefficient or a voltage standing wave ratio (VSWR) value (amplitude value) based on the forward feedback signal (e.g. a power of the forward feedback signal) and the reverse feedback signal (e.g. a power of the reverse feedback signal). The feedback receiver module or the control module (e.g. control module 101) may also be configured to determine a phase offset value based on the forward feedback signal and the reverse feedback signal (e.g. a phase offset between the forward feedback signal and the reverse feedback signal), for example.

The determined phase offset value and VSWR value may be used to determine a control code (e.g. a first or starting default control code) which may be used by the control module to generate the control signal for adjusting an impedance of the variable impedance matching circuit. The default control code may be a control code by which reasonable impedance matching may be expected (e.g. a control code with which a performance indicator meets a threshold performance value, such as a power delivery improvement (PDI) value), for example. Further control codes may be tested in order to improve or to optimize the performance value, e.g. to improve the power delivery improvement value, for example. The further control codes to be tested may be selected based on the default control code, for example.

Using the feedback receiver module and/or the control module to determine the (first or starting) default control code may allow the default control code to be determined easily (e.g. by a reduced number of iterations). In some examples, the feedback receiver module may optionally be omitted from the apparatus. Instead of determining the (first or starting) default control code based on a VSWR amplitude and/or phase value determined by the feedback receiver module or the control module, the default control code may be determined iteratively. However, this may require a larger number of iterations.

The control module 101 may be configured to generate the control signal based on a selected control code, for example. Due to the control module 101 of the apparatus 100 being configured to generate the control signal 102 based on the sensor signal 103, the control signal 102 may be generated based on a power radiated by the antenna module.

The control module 101 may be configured to select a control code from a plurality of control codes stored in a memory module (e.g. a non-volatile memory circuit), for example. The control module 101 may be configured to generate the control signal 102 for adjusting an impedance of at least part of the variable impedance matching circuit, for example. In some examples, the plurality of control codes may be predetermined control codes associated with predetermined VSWR (amplitude) and phase values. The plurality of control codes may be arranged in one or more code sets, for example according to predetermined VSWR amplitude values.

The (at least one) control code may include impedance adjustment information for adjusting an impedance of at least one adjustable impedance component of the variable impedance matching circuit. For example, the variable impedance matching circuit may include between two to four variable impedance components (e.g. capacitors or inductors). The impedance adjustment information may include at least one of a capacitance value and an inductance value for adjusting the impedance of at least part of the variable impedance matching circuit, for example.

The control module 101 may be configured to select a control code as a default adjustment code, for example (e.g. during power on, the default control code may be based on a measured VSWR amplitude and phase value). The control module 101 may be configured to further select a sequence of further control codes for generating a sequence of further control signals for adjusting an impedance of at least part of the variable impedance matching circuit (e.g. of the adjustable impedance components), for example. For example, the control module 101 may be configured to circle around the default adjustment code to identify a code which provides a bigger or maximum power to the antenna module. The control module may be configured to select (with a selection frequency) different control codes, for example. The frequency of code selection may be different or the same as the sensing frequency of the sensing measurements carried out by the sensor circuit, for example. In some examples, the control module may be configured to select different control codes for generating the control signal at a time interval of between 10 μs to 30 μs.

Due to the codes for tuning the variable impedance matching circuit being selected based on the power of the electromagnetic signal radiated by the antenna module, this may reduce the dependency of code selection on impedance variations due to the variable impedance matching circuit itself (e.g. an antenna tuner), for example. The generation of the control signal may also be less sensitive to fluctuations or interferences due to load variations in the antenna module and other circuit components (e.g. a coupler circuit or circuit components of the printed circuit board), for example.

Existing mobile application (smartphones, tablets) depend highly on internal antenna efficiency due to the influence (or interference) of human body parts on the antenna (e.g. influence from hands and/or head). In the technical domain, these interferences may correspond to strong mismatching of the internal antenna, for example. Mismatching may be characterized by a new VSWR (e.g. amplitude) and/or phase of the antenna impedance, for example. By default, antenna impedance may be considered to be 50Ω) (VSWR=1 and any angle), for example. However, in cases of mismatching, the VSWR may reach values up to 11 to 13 and even more, for example. Mismatching losses together with transducer gain losses may reach values of 12 to 14 dB in some cases. Therefore, for 2G (second generation wireless technology), power may drop from 1 Watt to 63 mW, for example. For example, 12 dB may result in power being 15.8 times smaller, for example.

Placement of the field sensor about (or in proximity to) the antenna, together with tracking algorithms may significantly increase the radiated power at all possible Z ANT (antenna impedances) due to head and/or hands influences (or other interferences), for example. Additionally, management of the antenna tuner results in low sensitivity to tolerances of the antenna tuner (AT), coupler and components of the PCB (e.g. printed circuit board), ensuring a maximum available radiated power in any case for any applied frequency. An applied self-study algorithm for AT codes may improve functionality. For example, steady-state solutions may be carried out much faster. A code set rotation around a temporary optimal set (e.g. a default code set) may be used for the TX (e.g. transmitter) and the RX (receiver) chain of a transceiver, thereby avoiding dominating only the TX and making it imbalanced.

The field sensor (e.g. the sensor circuit) 113 may be added to control the radiated power, for example. This added sensor allows Z ANT (the impedance of the antenna module) to be tracked easily, for example. After Z ANT testing (e.g. VSWR amplitude and phase testing using the coupler module and the feedback receiver) and choosing a new AT (antenna tuner) code (e.g. a default control code), the firmware begins to loop through the codes around the chosen code set and the sensor tests for the code which gives bigger power, for example. The code with a bigger power may be named as “new updated”, for example. Circling around the “new updated” code will be continued immediately to find new optimal codes, for example. The system therefore uses the best AT code set which gives biggest power in the antenna.

The field sensor (e.g. the sensor circuit) 113 may be placed near the antenna, which is sensitive enough to make conditional field measurements of power radiated by antenna module, for example. The sensor does not degrade antenna performance, for example. Physically, the sensor may be implanted or may be a chip inductor or micro strip inductor connected to the current feedback receiver (FBR) or Schottky Diode (e.g. the Schottky diode detector) or even the receiver chain functioning as the RF power tester (r.m.s). The sensor circuit may estimate all manipulations with the AT (antenna tuner) codes from the view point of actual (e.g. really) radiated (r.m.s) power, for example.

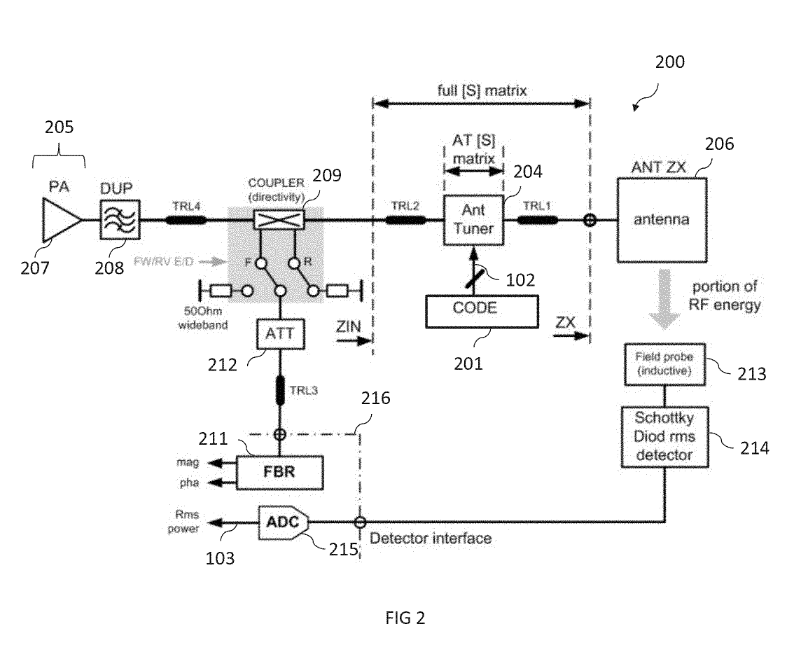

FIG. 2 shows a schematic illustration of a transmitter arrangement 200 including an apparatus for providing a control signal for a variable impedance matching circuit 204.

The transmitter arrangement 200 may at least include a power amplifier 207 (PA), a coupler module 209 (e.g. a radio frequency RF coupler), a feedback receiver module FBR 211 (for RF measurements), transmission lines (e.g. TRL1 to TRL4) which may be pieces of 50Ω micro strip lines, and a variable impedance matching circuit 204 (e.g. a switchable antenna tuner AT). The transmitter arrangement 200 may include a transmitter module 205 (which may include the power amplifier (PA) 207 and other circuit components) and an antenna module 206 which may have a changeable complex antenna impedance ANT ZX.

The transmitter module 205 may be configured to generate a high frequency transmit signal to be transmitted from the transmitter module 205 to the antenna module 206 to be radiated by the antenna module, for example. For example, the transmitter module 205 may be configured to perform at least an up-conversion (e.g. and optionally amplifying and filtering) of a baseband signal (e.g. having a frequency bandwidth located in the baseband domain of less than 100 MHz or less than 500 MHz) to a radio frequency domain of the apparatus. This may be carried out by mixing the baseband signal with an oscillator signal in order to generate the high frequency transmit signal (e.g. a radio frequency signal) to be sent to an external receiver or to be delivered to the antenna module.

The (high frequency) transmit signal may include signal portions with one or more frequency bands (e.g. located between 500 MHz and 10 GHz), for example. The transmitter module 205 may further include or be coupled to a power amplifier 207 for amplifying the high frequency transmit signal, for example. In some examples, the transmitter module 205 may be part of or include a transceiver module configured to perform an up-conversion of baseband signals to high frequency transmit signals and to perform a down-conversion of high frequency received signals to low frequency base band signals. The transmit signals may be transmitted and received by the antenna module, for example.

The transmitter arrangement 200 may include a duplexer module (DUP) 208. The duplexer module 208 may be configured to allow transmission signals having a transmission frequency and receiver signals having a different receiver frequency to be transmitted or received using the same antenna module. The transmitter (or transceiver) module 205 may be coupled to the duplexer module 208. The duplexer module may be coupled to the coupler module 209 via at least one transmission line TRL4.

The transmitter arrangement 200 may include a coupler module 209. The coupler module 209 may be located (or coupled) between the transmitter module 205 and the antenna module 206. For example, the coupler module 209 may be located (or coupled) between the transmitter module 205 and the variable impedance matching circuit 204. For example, the coupler module 209 may be located (or coupled) between the duplexer module 208 and the variable impedance matching circuit 204. The transmitter module 205 may be coupled to the variable impedance matching circuit 204 via duplex module 208, the coupler module 209 and the at least one transmission line TRL4, for example. For example, the transmission line TRL4 may couple the duplex module 208 to the coupler module 209, for example.

The coupler module 209 may be configured to provide a forward feedback signal based on the high frequency transmit signal provided by the transmitter module and a reverse feedback signal based on a reflected portion of the high frequency transmit signal received from the antenna module 206, for example. The coupler module 209 may be coupled to the variable impedance matching circuit 204 via at least one transmission line TRL2, for example.

The coupler module 209 (e.g. implemented as a 4-port directional coupler or two 3-port direction couplers) may include an input port, an output port, a forward-coupled port (F) and a reverse-coupled (R) port. All ports may be matched to a characteristic impedance (e.g. to a 50Ω load at wideband frequency). Control signals (e.g. FW/RV and e.g. E/D) may be generated by the control module 201 to control the coupling of the ports of the coupler module 209. For example, the control signals may control a coupling of the forward-coupled port and the reverse-coupled port to the characteristic impedance (e.g. a resistor) and/or to an attenuator module 212, for example. The input port may be coupled to the transmitter module 205 by an electrical connection or through one or more other electrical elements (e.g. power amplifier and/or filter), for example. The output port may be configured to be coupled to the antenna module 206 of the variable impedance matching circuit 204 by an electrical connection or through one or more other electrical elements (e.g. antenna switch and/or filter), for example. A signal obtained at the forward-coupled port may be mainly caused by a signal provided to the input port, for example. A signal obtained by the reverse-coupled port may be mainly caused by a signal received at the reverse-coupled port, for example. In other words, the forward feedback signal provided at the forward-coupled port may be mainly caused by the transmit signal received at the input port and the reverse feedback signal may be mainly caused by a reverse wave signal (e.g. caused by an antenna mismatch or by a reflection at an object in the proximity of the apparatus) received at the output port.

The (high frequency) transmit signal may be provided to an input port of the coupler module, for example. A main portion of the transmit signal may be provided from the output port of the coupler module 209 to the antenna module 206. A minor portion of the transmit signal may be provided to a forward-coupled port of the coupler module due to the coupling of the forward-coupled port and the input port of the coupler module (resulting in the forward feedback signal). Afterwards, the transmit signal may be transmitted by the antenna module 206, although a part of the transmit signal may be reflected due to an antenna mismatch (e.g. due to a varying impedance load of the antenna) and/or one or more reflections of signal portions at objects in the proximity of the apparatus (echoes), for example.

The forward feedback signal may be derived from the transmit signal. For example, the forward feedback signal may be a part of the transmit signal itself or the transmit signal may cause the forward feedback signal by capacitively or inductively coupling of the transmit path with a coupling element (e.g. directional coupler or transformer arranged close to the transmit path) of the coupler module 209. For example, the apparatus 200 may include a directional coupler representing the coupler module 209 arranged in the transmit path (e.g. after amplification of the transmit signal). A directional coupler 209 may derive the forward feedback signal (at the forward-coupled port) from the transmit signal (applied to the input port).

Similarly, the reverse feedback signal may be derived from the transmit signal. The reverse feedback signal may be generated based on a reflected portion of the transmit signal received by the antenna module 206 from the transmitter module 205. In other words, the reverse feedback signal may be mainly caused by a reverse wave signal (e.g. caused by an antenna mismatch or by a reflection at an object in the proximity of the apparatus) received at a port connected to the antenna module 206 or the variable impedance matching circuit 204. For example, the reverse feedback signal may be a part of the reverse wave received at the output port of the coupler module 209 itself. The reverse wave signal received at the output port may cause the reverse feedback signal by capacitively and/or inductively coupling of the reverse transmit path with a coupling element of the coupler module 209 (e.g. directional coupler or transformer arranged close to the transmit path).

The coupler module 209 may be coupled to a feedback receiver module 211, and the feedback receiver module 211 and/or the control module 201 may be configured to determine the VSWR value (e.g. mag output) or the phase offset value (pha) based on the forward feedback signal and the reverse feedback signal, for example. The coupler module 209 may be coupled to the feedback receiver module 211 via an attenuator module 212 and at least one transmission line TRL3 coupled between the feedback receiver module 211 and the attenuator module 212. The feedback receiver module 211 may be connected to the attenuator module 212 via a detector interface 216.

As the full [S] matrix (e.g. a scattering matrix comprising values related to an impedance of the AT, the transmission lines TRL1 and TRL2) and the AT [S] matrix (a scattering matrix comprising values related to an impedance of the AT) are not always known, the default control code determined based on may not always provide optimal impedance matching between the transmission lines and the antenna module.

Therefore, the transmitter arrangement 200 may include a sensor circuit 213 configured to measure power of a radio frequency (RF) signal radiated by the antenna module, so that control codes for controlling or varying the variable impedance matching network 204 may be based on the actual power radiated from the antenna module.

The sensor circuit 213 (e.g. an inductive field probe) may be positioned at a distance of between 5 mm to 5 cm from the antenna module 206. The sensor circuit 213 may be configured to measure a portion of the radio frequency (RF) energy radiated by the antenna module 206, for example. The sensor circuit 213 may be coupled to a detector circuit 214 (e.g. a r.m.s detector, e.g. a Schottky diode r.m.s detector) configured to produce a r.m.s signal. The detector circuit 214 may be coupled to an analog to digital converter circuit ADC 215 configured to produce a digital r.m.s sensor signal including r.m.s power information related to the power of the electromagnetic signal radiated by the antenna module. The ADC circuit 215 may be connected to the detector circuit 214 respectively via a detector interface (e.g. 216).

The ADC circuit 215 may be configured to provide the (digital) sensor signal to the variable impedance matching circuit 204, for example. The control module 209 may be configured to loop through a plurality of further control codes (e.g. a sequence of further control codes) around the chosen default control code, while the sensor circuit 213 measures the power of the electromagnetic signal radiated by the antenna module based on the sequence of further control codes.

The variable impedance matching circuit 204 may be coupled to the antenna module via at least one transmission line TRL1, for example. The antenna tuner AT (e.g. the variable impedance matching circuit) 204 may be used to increase power delivered to the antenna. The AT may be tuned to the default antenna impedance which in common case may not necessarily be equal to 50Ω. The AT may have two to four switchable capacitors changeable by codes. In real maintenance, the measurement system defines current antenna impedance that is changing continuously. The measured impedance may be dynamically matched by new AT codes to 50Ω or other needed impedance.

The control module 201 may be coupled to the variable impedance matching circuit 204, and may be configured to generate a control signals based on a selection of control code. The control module 201 may be configured to generate a control signal (e.g. a first default control signal) based on a selection of a control code based on the forward feedback signal and the reverse feedback signal. For example, the control module may be configured to select the control code (as a default control code) based on a voltage standing wave ratio (VSWR) amplitude value and a phase offset value derived from the forward feedback signal and the reverse feedback signal. Subsequently, the control module 201 may be configured to generate one or more further control signals based on code circling around the default control code, to determine an improved default control code.

The antenna tuner AT adaptation procedure may include the coupler ports (forward and reverse) being measured by the feedback receiver and ZIN being calculated. ZIN may be the (complex) input impedance measured at the AT-TRL2 pair, for example. The antenna tuner AT may be loaded by (or may have) an unknown complex impedance ZX-TRL1. Then, the board software may calculate or determine (the actual value of) the complex impedance ZX. ZX may be the complex impedance including a piece of TRL1 and the antenna module impedances (Z ANT). ZX (actual) presented as VSWR/PHASE (e.g. a VSWR amplitude and phase) directly shows which code set (e.g. which default code set) must be chosen, for example. Several code sets may be saved at the board, for VSWR=3, 5, 7, 9 . . . 13 and phases with step 22.5 degree. The board software may establish proper code set for tuning the antenna tuner AT. ZX adaptation is completed.

Errors in the [S] matrix definition may lead to strong PDI degradation, from possible 7 to 9 dB to moderate 2 to 3 dB and sometimes 0 to −2 db. Factory calibration cannot completely solve this problem, as the only unknown impedance Z ANT can be properly calibrated and measured, however, the AT and TRL1/TRL2 matrix is unknown.

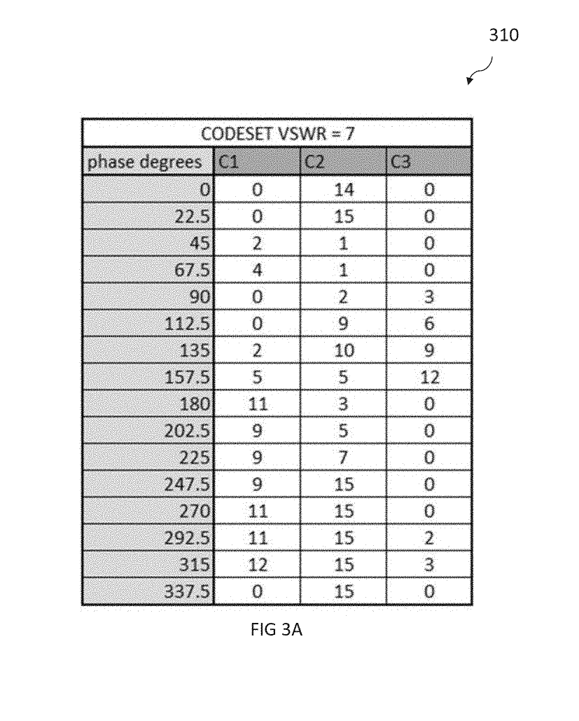

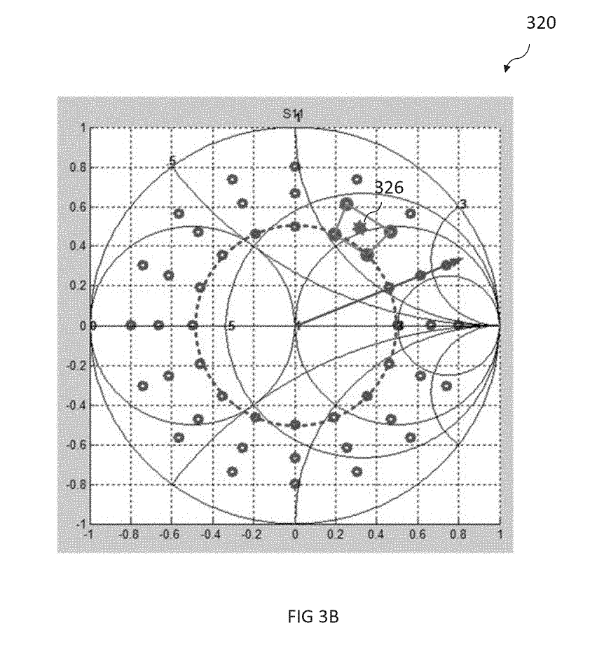

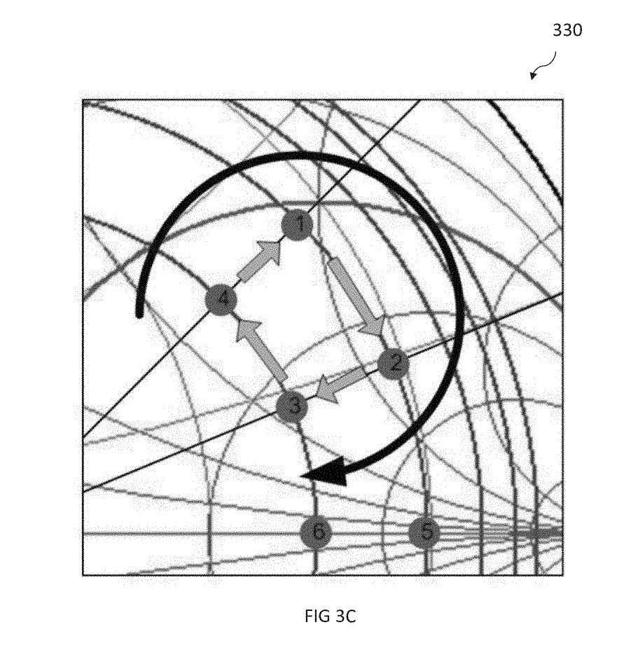

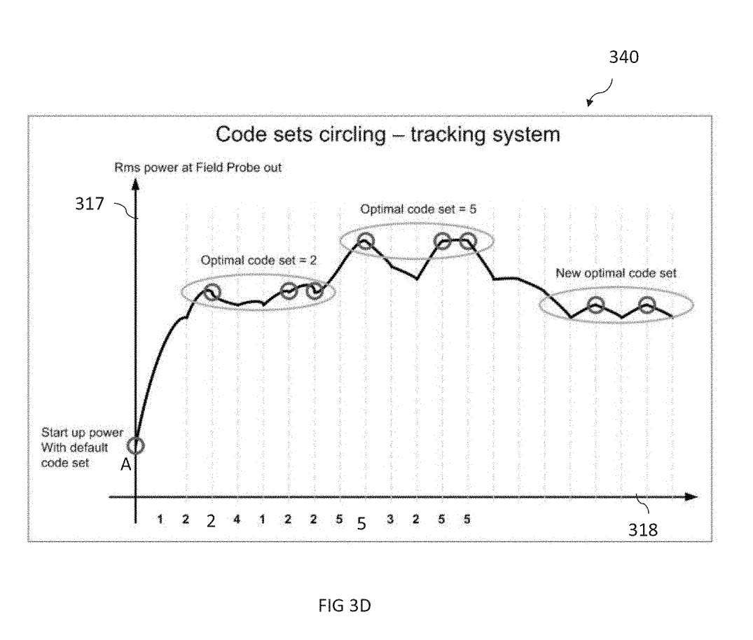

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the transmitter module, the coupler module, the feedback receiver module, and the transmission lines) The examples shown in FIG. 2 may comprise one or more optional additional features corresponding to one or more aspects mentioned in connection with the proposed concept or one or more examples described above (e.g. FIG. 1) or below (e.g. FIGS. 3A to 8).

FIGS. 3A to 3C show schematic illustrations of code selection according to an example.

FIG. 3A shows an example of a code set 310. Each control code may include impedance adjustment information. For example, each code set may include or contain decimal codes (C1, C2, C3) to tune a plurality of adjustable components

The control module (e.g. 101, 201) may be configured to generate the control signal based on a selected control code from the code sets, for example. Each code set may include a plurality of control codes. The control codes in one code set may be associated with the same predicted predetermined voltage standing wave ratio value but different predetermined phase offset values. For example, FIG. 3A shows a code set with VSWR=7, and VSWR phase values differing according to 22.5 degree step increments.

The code sets may be generated in advance in a laboratory for averaged antenna tuner AT and transmission line TRL1/TRL2 characteristics. For example, the predetermined or pre generated control codes may include different impedances adjustment values characterized according to different VSWR or phase values, for matching an antenna module impedance to a transmission line impedance (e.g. a 500 impedance). A code set such as that shown in FIG. 3A may correspond to impedances shown in FIG. 3B. The plurality of codes (and code sets) may be stored in a memory module (e.g. a non-volatile memory circuit) which may be implemented as part of the apparatus (e.g. on the same semiconductor chip as the control module), or on as different semiconductor chip.

FIG. 3B shows a plot 320 of calculated or measured antenna impedances and phases corresponding to antenna tuner code sets.

For example, FIG. 3B shows calculated or measured antenna impedances Z Ant characterized by VSWR=3, 5, 7 and all phases. The corresponding (guaranteed matching) antenna tuner AT code sets may be saved in the memory. Every antenna impedance Z Ant angle (e.g. 360/16=22.5 degrees) may be represented by corresponding codes C1, C2 C3. Code sets may exist for every VSWR=3, 5 to 13. Every code set may have 16 sub-groups for every 22.5 degree step. The star 326 shows the measured Z Ant, that corresponds to a VSWR between 5 and 7, and/angle between 45 and 67.5 degrees, for example. Surrounding codes 327 may be tested in a code set loop starting with a first default control code in order to determine a control code which results in a maximum radiated power by the antenna.

FIG. 3C shows an example of a code set loop 330 according to an example. The control module may be configured to select the (first) default control code (e.g. code 1) based on the VSWR and the phase offset value measurement provided by the feedback receiver module, for example. The control module may then begin to loop through the codes around the (first) default control code.

As shown in FIG. 3C, every subframe (e.g. every 1 ms, for example, for LTE), the control module may jump to a new code set (e.g. starting from code 1, then code 2, then code 3, then code 4), for example. In other words, the control module may select one or more further control codes. The control module may receive the sensor signal corresponding to each selected further control code. Based on the field probe r.m.s output measurements, the control module may determine which code produces a bigger or larger radiated output power.

As an example, code 1 and code 2 may have the same VSWR value, but different phase values, and codes 3 and 4 may have the same VSWR value (different from code 1 and code 2), and different phase values, for example. Codes 1 and 4 may have the same phase but different VSWR value, and codes 2 and 3 may have the same phase (different from codes 1 and 4) but different VSWR values, for example. As a result, a better phase and better VSWR code set may be recognized.

Based on the default control code (e.g. code 1), the control module may be configured to select the plurality or sequence of further control codes. For example, the control module may be configured to select the sequence of further control codes based on a predetermined voltage standing wave ratio value and a predetermined phase value associated with the default control code. In some examples, at least one further control code in the sequence of further control codes may include impedance adjustment information associated with the same predetermined voltage standing wave ratio value or the same predetermined phase value as the default control code. For example, if code 1 were the selected default control code, code 2 may have the same predetermined VSWR value as code 1, but a different phase value, for example.

In some examples, one of the further predetermined voltage standing wave ratio value and the further predetermined phase value associated with a further control code in the sequence of further control codes is the same as a previous further control code in the sequence of further control codes. For example, if code 1 were the selected default control code, code 2 may have the same predetermined VSWR value and a different phase value from code 1. code 3, may have the same phase value and different predetermined VSWR value from code 2. Code 4 may have the same VSWR value and a different phase value from code 3.

In some examples, each further control code in the sequence of further control codes may include impedance adjustment information associated with a further predetermined voltage standing wave ratio value and a further predetermined phase value. The further predetermined voltage standing wave ratio value and the further predetermined phase value may lie within a threshold range of the predetermined voltage standing wave ratio value and a predetermined phase value associated with the impedance adjustment information of the default control code. For example, further control codes 2 to 4 may be selected to be part of the sequence of further control codes if they lie within a threshold range of code 1 (the default control code).

The control module may be configured to select a further control code as a (new temporary) default control code based on a power of an electromagnetic signal radiated by the antenna module based on the further control code. For example, the selection of the new temporary default control code may be based on the sensor signal provided by the sensor circuit based on the radiated power measured at the antenna module. For example, the control module may be configured to select a further control code as the default control code if the sensor signal indicates that an increase in power of the electromagnetic signal is produced based on the further control code. For example, the control module may be configured to select a further control code of the plurality of further control codes as the default control code if the sensor signal indicates that a largest increase in power of the electromagnetic signal is produced based on the selected further control code.

Optionally, additionally or alternatively, the control module may be configured to select a control code as a default control code and to generate an adjusted control code based on an adjustment of the impedance adjustment information of the default control code. The adjusted control code may be used for generating a further control signal for adjusting an impedance of at least part of the variable impedance matching circuit.

For example, the control module may be configured to adjust the impedance adjustment information by varying at least one of a capacitance value and an inductance value by a predetermined adjustment value.

For example, the control module may be configured to update a code set with an adjusted control code including adjusted impedance information if the sensor signal indicates that an increase in power of the electromagnetic signal is produced based on the adjusted control code.

For example, the control module may be configured to select an adjusted control code including adjusted impedance information as the default control code if the sensor signal indicates that an increase in power of the electromagnetic signal is produced based on the adjusted control code.

Factory downloaded code sets may be optimal for certain average combinations of AT+TRL1/TRL2. However, the real pair (or real values of) AT/TRL may differ from expected and may be difficult to be estimated by calibration and/or measurements. The presence of the sensors of field (e.g. a field sensor) may allow for the adjustment of chosen code sets (from predefined LUT). For example, using a self-study procedure of used code sets, a sweep may be carried out for C1 (e.g. a first sub code, which may be used for adjusting a first adjustable component, for example) in the range value+/−1. (For example, the impedance information related to each adjustable component may be adjusted in step-wise increments e.g. using a step-wise addition or subtraction of impedance values.)

If the sensor signal increases (e.g. if a larger power is radiated by the antenna module, the control code may be updated with the adjusted increment information. For example, if the sensor circuit confirms that the power measured with the new sub code becomes bigger, C1 value may be rewritten to newly test. The control code may also remain unchanged if the radiated power does not increase), for example. The same adjustment process may be carried out for each of the adjustable components. For example, the same may be done for C2 and/or C3 sub codes. Gradually all C1/C2/C3 (e.g. all sub codes) used for any possible VSWR (amplitude) and phase value may be rewritten (updated). This may improve (averaged) radiated power because although the AT initially uses the best codes, the AT codes to the concrete [S] matrix (e.g. scattering matrix) may have parameters which cannot be defined with appropriate exactness. For 0.2 seconds or shorter, the chosen code set (for concrete VSWR/Phase) may be updated and rewritten in firmware FW, for example.

FIG. 3D shows a plot 340 of measured r.m.s power 317 (e.g. r.m.s power at field probe out) versus code selection 318, according to an example. For example, FIG. 3D shows the output (power) of the sensor circuit during code set circling.

Point A shows for example, the start up power with a default chosen code set, for example. The default code set may be selected, e.g. after the Z ANT testing, for example. As the firmware begins to loop through the codes around the chosen code set, the sensor tests for the code which gives bigger power. Different code sets (or codes) may be selected (e.g. a code set 2, or code set 5) until a new optimal code set is selected. The code with a bigger power may be named as “new updated”. Circling around the “new updated” code may continue immediately to find new optimal codes. So the system always uses the best AT code set which gives biggest power in the Antenna.

It may be understood that searching for the best code set may be an optimization or improvement procedure for minimum transducer losses with an appropriate return loss coefficient at the AT input (PA output). The selected code set (for example, for the first default code set at power up) may be optimal for certain averaged conditions: e.g. with nominal TRL1/TRL2, nominal AT characteristics. Tolerance of the mentioned components may lead to lower efficiency and lower radiated power in comparison to the maximum available power.

To compensate for the losses explained by the tolerance, a calibration procedure may be used, for example. The factory calibration may be performed by connecting a known calibration impedance, e.g. a Z CALIB impedance, and correction measured ZIN impedance to an expected value. Such an approach allows the measurement of the unknown ZANT (antenna impedance) with a good accuracy, although TRL1/TRL2 and AT tolerance itself may not necessarily be estimated accurately. The reason for this may be due to PA/TX (e.g. power amplifier/transmission) leakage to the F/R (forward and reverse) inputs of the coupler (−40 . . . −60 dBc) and mismatching between the F/R outs (ports) (+/−1 dB).

Therefore, the cause of TRL1/TRL2 and AT measurement error is not necessarily distinguished. This may be due to tolerance only or it may be corrupted by coupler imperfection as well or all reasons together. ADS simulation may demonstrate the size of an uncertainty zone explained by all factors: components tolerances and coupler imperfections. As a result, even after a calibration, a selected code set may be shifted by an angle and VSWR value compared to the real full [S] matrix (e.g. scattering matrix comprising impedance values related to or taking into account impedance values of the antenna tuner and transmission lines TRL1 and TRL2). Power Delivery Improvement (PDI) analyzed for concrete AT characteristics show that if a chosen code set and [S] matrix are not matched to each other (due to calibration imperfections), PDI (power delivery improvement) may strongly degrade proportionally to mismatching. PDI degradation may also be caused by 1, 2 and 4 mm of additional transmission lines inserted between the AT and the antenna module due to CODESET and [S] matrix mismatching. Strong PDI degradation may be due to a wrongly calibrated [S] matrix. Adding 1, 2 and 4 mm of strip line may be equivalent to a rotation [S] matrix corresponding to a 7.5 degree, 15 degree and 30 degree rotation, for example. If the code set is artificially rotated to +30 degrees to compensate for a 4 mm strip line influence, the PDI may recover to much better values, for example.

Antenna tuning with predefined code sets saved in a memory may compensate for antenna mismatching. However, it may be insufficient for attaining maximum power radiated by the antenna module.

The antenna tuner AT adaptation procedure may include the coupler ports (forward and reverse) being measured by the feedback receiver and ZIN being calculated. ZIN may be the (complex) input impedance measured at the AT-TRL2 pair, for example. The antenna tuner AT may be loaded by (or may have) an unknown complex impedance ZX-TRL1. Then, the board software may calculate or determine (the actual value of) the complex impedance ZX. ZX may be the complex impedance including a piece of TRL1 and the antenna module impedances (Z ANT). ZX (actual) presented as VSWR/PHASE (e.g. a VSWR amplitude and phase) directly shows which code set (e.g. which default code set) must be chosen, for example. Several code sets may be saved at the board, for VSWR=3, 5, 7, 9 . . . 13 and phases with step 22.5 degree. The board software may establish proper code set for tuning the antenna tuner AT. ZX adaptation is completed.

The code set must (or may) be chosen at the board upon Z ANT (or ZX) measurement (VSWR and angle) using the coupler modules (forward and reverse ports). The calibration may allow the impedance Z ANT to be measured but does not allow to estimate AT and TRL1/TRL2 tolerances.

Using the method of look up tables LUT (for predefined code sets) may lead to essential PDI degradation due to limited calibration ability to predict accurately AT+TRL1/TRL2 (the antenna tuner impedances) and thus the [S] matrix. An attempt to use reflected power (at the reverse port of Coupler) may improve return loss, but may degrade the PDI due to the opposite direction (often) of return loss and transducer gain direction vs. phase of Z ANT.

By code circling around the chosen default control code, the selected control code may be based on the actual radiated power, and dependence on the unknown antenna tuner impedance may be reduced, for example. Furthermore, by code circling, instead of forcing the AT to return to an initial condition or reference code in order to make new impedance test when an impedance change is experienced in the antenna, new codes may be chosen around the selected default code. Therefore, power drops in the antenna, which may normally be associated with a transition back to the reference code position are avoided, for example. For example, there is no evident criterion of antenna impedance varying, and clear information about it (e.g. the extent of antenna impedance variation) is not necessarily known before returning to the reference code and to measure ZANT one more time. So such an action would have to be done forcibly. As a result, it may be impossible to avoid power drops. Return losses (from the reverse port of the coupler) cannot be used for testing impedance changes accurately due to very small signals at this port, opposite direction of return losses and changes in transducer gain.

Errors in the [S] matrix definition may lead to strong PDI degradation, from possible 7 to 9 dB to moderate 2 to 3 dB and sometimes 0 to −2 db. Factory calibration cannot completely solve this problem, as the only unknown impedance Z ANT can be properly calibrated and measured, however, the AT and TRL1/TRL2 matrix is unknown. Code circling carried out by the control module of the apparatus and described with respect to FIGS. 3A to 3D may circumvent these challenges, for example.

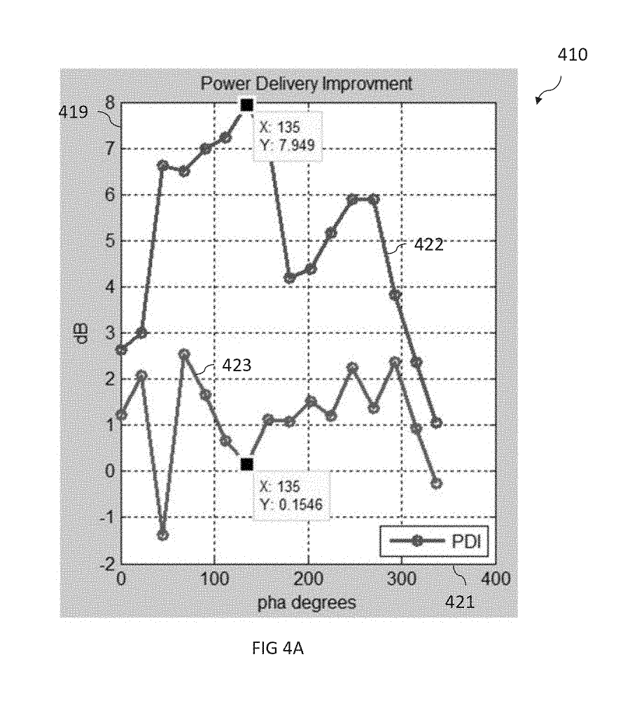

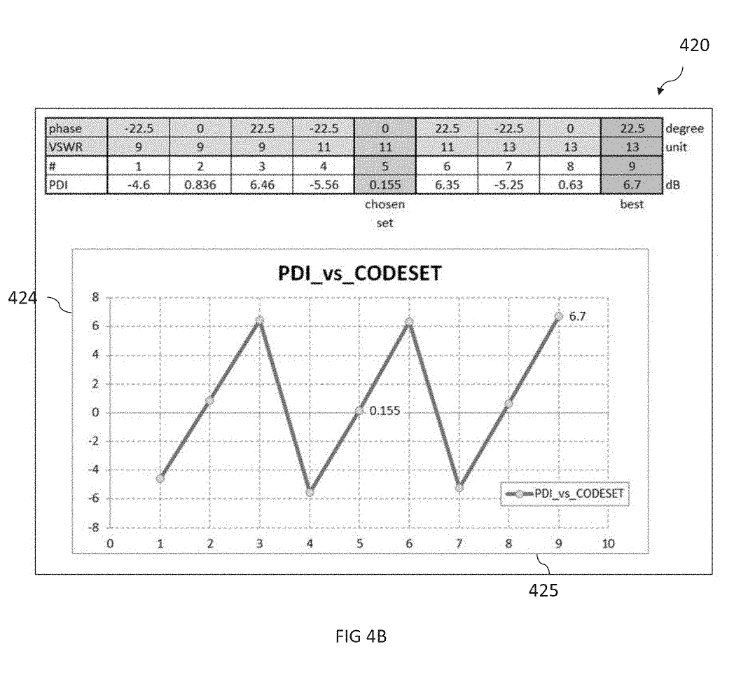

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the code circling, code adjustments the transmitter module, the coupler module, the feedback receiver module, and the transmission lines) The examples shown in FIGS. 3A to 3D may comprise one or more optional additional features corresponding to one or more aspects mentioned in connection with the proposed concept or one or more examples described above (e.g. FIGS. 1 and 2) or below (e.g. FIGS. 4A to 8).

FIGS. 4A and 4B shows an example of code looping or circling in an apparatus for providing a control signal for a variable impedance matching circuit according to an example.

FIG. 4A shows a plot 410 of PDI (dB) 419 versus phase (degrees) 421. FIG. 4A further shows an ideal case 422 of PDI and a case 423 where a wrong [S] matrix including or based on coupler imperfections and AT tolerance. In this example, frequency=1950 MHz, VSWR case=11, VSWR phase=135 degree, [S] Matrix, ideal and “shifted” by 4 mm of uncompensated TRL.

FIG. 4A shows the PDI for the ideal [S] matrix 422 and matrix corrupted 423 by an uncompensated TRL of 4 mm. This 4 mm imitates total [S] matrix corruption due to coupler imperfections, AT tolerance and TRL1/2 tolerances. The PDI degradation may be 7.8 dB. code set circling may be started around a chosen point, using VSWRs and phase shifts as shown in FIG. 4B.

FIG. 4B shows a plot 420 of PDI 424 versus code set 425. FIG. 4B shows that a PDI for a chosen (initial) code set (VSWR=11, phase 137.5 degree) may have a very small value, PDI=0.155 dB. When monitoring sensor out, code set #9 (VSWR=13, phase=137.5+22.5=160 degrees) may be identified as the best code set. For example, it gives PDI=6.7 dB or 6.5 dB of improvement compare to the initial case (code set #5). The proposed example shows the ability of the method to define the best code set during code swiping. At the same time, a phase step of ±22.5 degrees may result in a power drop which is too big (with concrete considered antenna tuner). Smaller phase steps of about ±8 to 16 degrees may be used if required. For such smaller phase steps, the size of a full code set may become bigger and getting an optimal code during tracking may take a longer time. However, big power drops may be avoided and communication may become more stable.

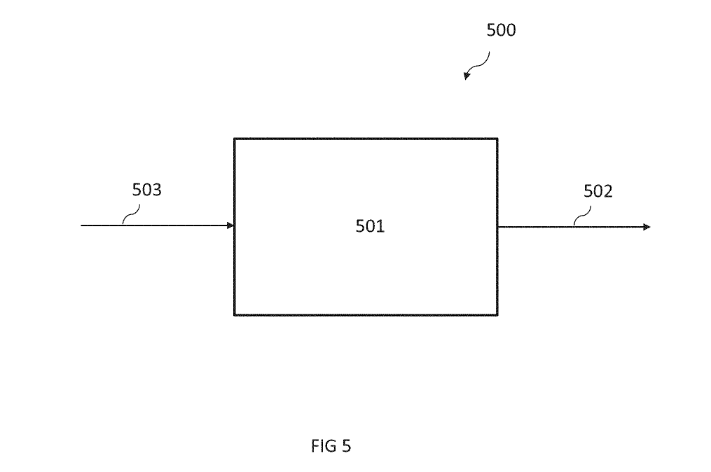

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the code circling, code adjustments the transmitter module, the coupler module, the feedback receiver module, and the transmission lines) The examples shown in FIGS. 4A and 4B may comprise one or more optional additional features corresponding to one or more aspects mentioned in connection with the proposed concept or one or more examples described above (e.g. FIGS. 1 to 3) or below (e.g. FIGS. 5 to 8).

FIG. 5 shows a schematic illustration of signal generation means 500 according to an example.

The signal generation means 500 includes a means 501 for generating a control signal configured to generate a control signal 502 for adjusting an impedance of at least part of a variable impedance matching circuit coupled to an antenna module.

The means 501 for generating a control signal is configured to generate the control signal 502 based on a sensor signal 503 received from a sensor circuit located in proximity to the antenna module.

The sensor signal 503 includes information related to a power of an electromagnetic signal radiated by the antenna module.

Due to the adjustment of the variable impedance matching circuit based on a power actually radiated by the antenna module, the radiated power may be adjusted and/or controlled more accurately. This may lead to an improved performance of a transmitter module in which the apparatus is implemented, for example.

For example, the sensor signal 503 may include information related to a power of a magnetic field component of the electromagnetic signal radiated by the antenna module. For example, the sensor circuit may include a field probe circuit coupled to a detector circuit. The detector circuit may be configured to determine a r.m.s power of the electromagnetic signal radiated by the antenna module and sensed by the field probe circuit. The sensor circuit may include at least one of a magnetoresistive coil, a hall sensor circuit, a capacitive circuit, an inductive circuit, and a microstrip inductor circuit. The sensor circuit may be located at a distance of between 5 mm to 5 cm from the antenna module.

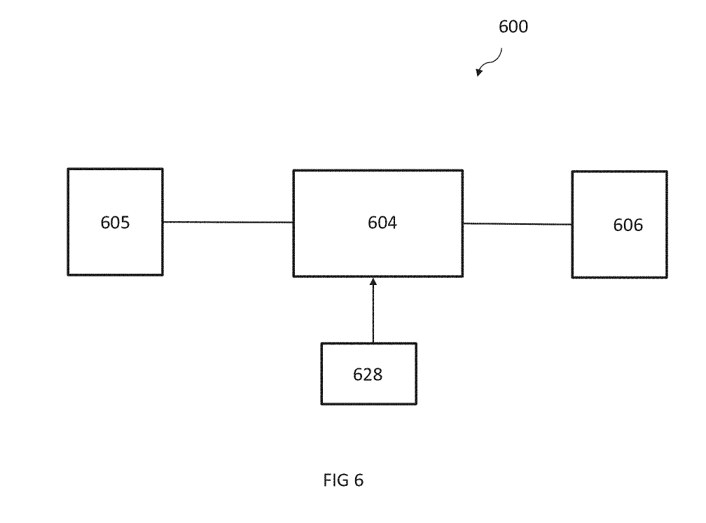

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the code circling, code adjustments the transmitter module, the coupler module, the feedback receiver module, and the transmission lines) The examples shown in FIG. 5 may comprise one or more optional additional features corresponding to one or more aspects mentioned in connection with the proposed concept or one or more examples described above (e.g. FIGS. 1 to 4B) or below (e.g. FIGS. 6 to 8).

FIG. 6 shows a schematic illustration of a transmitter 600 or transceiver according to an example.

The transmitter 600 includes a transmitter module 605 coupled to a variable impedance matching circuit 604. The transmitter module 605 is configured to generate a high frequency transmit signal to be transmitted by an antenna module 606.

The transmitter 600 further includes an apparatus 628 for providing a control signal for a variable impedance matching circuit 604 as described with respect to FIGS. 1 to 5.

The transmitter 600 further includes an antenna module 606 configured to radiate an electromagnetic signal based on the high frequency transmit signal.

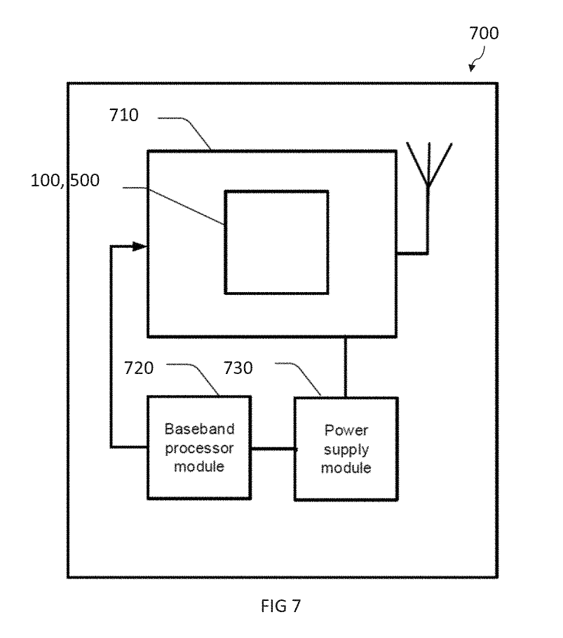

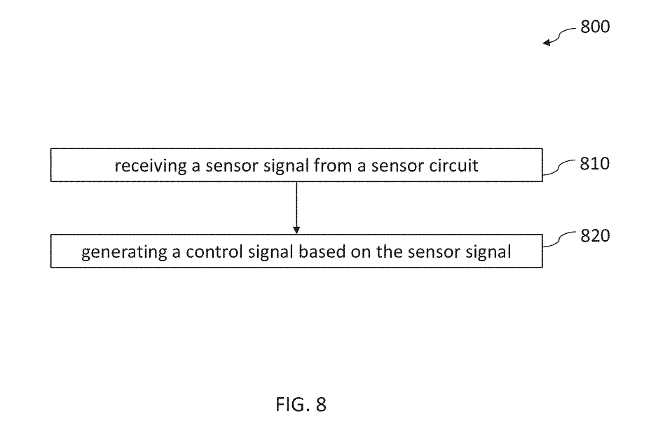

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the code circling, code adjustments the transmitter module, the coupler module, the feedback receiver module, and the transmission lines) The examples shown in FIG. 6 may comprise one or more optional additional features corresponding to one or more aspects mentioned in connection with the proposed concept or one or more examples described above (e.g. FIGS. 1 to 5) or below (e.g. FIGS. 7 and 8).

FIG. 7 shows a schematic illustration of a mobile device 700 and/or a cell phone. The mobile device 700 and/or a cell phone may include an apparatus for providing control signals (e.g. 100) or means for providing control signals (e.g. 500) which is implemented in or within a transmitter or a transceiver (e.g. 600). Further, the mobile device 700 includes a baseband processor module 720 generating at least the digital (e.g. baseband) signal to be transmitted and/or processing a baseband receive signal. Additionally, the mobile device 700 includes a power supply unit 730 supplying at least the transmitter or the transceiver module 710 and the baseband processor module 720 with power.

Further examples relate to a mobile device (e.g. a cell phone, a tablet or a laptop) including a transmitter or a transceiver described above. The mobile device or mobile terminal may be used for communicating in a mobile communication system.

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the code circling, code adjustments the transmitter module, the coupler module, the feedback receiver module, and the transmission lines) The examples shown in FIG. 7 may comprise one or more optional additional features corresponding to one or more aspects mentioned in connection with the proposed concept or one or more examples described above (e.g. FIGS. 1 to 6) or below (e.g. FIG. 88).

FIG. 8 shows a schematic illustration of a method 800 for providing a control signal for a variable impedance matching circuit according to an example.

The method 800 includes receiving 810 a sensor signal from a sensor circuit located in proximity to the antenna module, wherein the sensor signal includes information related to a power of an electromagnetic signal radiated by the antenna module.

The method 800 further includes generating 820 a control signal for adjusting an impedance of at least part of a variable impedance matching circuit coupled to an antenna module based on the sensor signal.

Due to the adjustment of the variable impedance matching circuit based on a power actually radiated by the antenna module, the radiated power may be adjusted and/or controlled more accurately. This may lead to an improved performance of a transmitter module in which the apparatus is implemented, for example.

Optionally, additionally or alternatively, the method 800 may further include selecting a control code from a plurality of control codes stored in a memory module, wherein the plurality of control codes are arranged in one or more code sets.

Optionally, additionally or alternatively, the method 800 may further include generating the control signal based on the selected control code.

Optionally, additionally or alternatively, the method 800 may further include selecting different control codes for generating the control signal at a time interval of between 10 μs to 30 μs.

Optionally, additionally or alternatively, the method 800 may further include selecting a control code as a default adjustment code and further selecting a sequence of further control codes for generating a sequence of further control signals for adjusting an impedance of at least part of the variable impedance matching circuit.

Optionally, additionally or alternatively, the method 800 may further include selecting a further control code as the default control code based on information related to a power of an electromagnetic signal radiated by the antenna module due to a further control signal generated by the control module based on the further control code.

Optionally, additionally or alternatively, the method 800 may further include selecting a further control code as the default control code if the sensor signal indicates that an increase in power of the electromagnetic signal is produced based on the further control code.

Optionally, additionally or alternatively, the method 800 may further include selecting a further control code of the plurality of further control codes as the default control code if the sensor signal indicates that a largest increase in power of the electromagnetic signal is produced based on the selected further control code.

Optionally, additionally or alternatively, the method 800 may further include selecting one control code as a default control code and generating an adjusted control code based on an adjustment of the impedance adjustment information of the default control code, and generating a further control signal for adjusting an impedance of at least part of the variable impedance matching circuit based on the adjusted control code.

Optionally, additionally or alternatively, the method 800 may further include adjusting the impedance adjustment information by varying at least one of a capacitance value and an inductance value by a predetermined adjustment value.

Optionally, additionally or alternatively, the method 800 may further include updating a code set with an adjusted control code including adjusted impedance information if the sensor signal indicates that an increase in power of the electromagnetic signal is produced based on the adjusted control code.

Optionally, additionally or alternatively, the method 800 may further include selecting an adjusted control code including adjusted impedance information as the default control code if the sensor signal indicates that an increase in power of the electromagnetic signal is produced based on the adjusted control code.

More details and aspects are mentioned in connection with the examples described above or below (e.g. the apparatus for providing control signals, the control module, the control signal, the variable impedance matching circuit, the adjustable components, the antenna module, the sensor signal, the sensor circuit, the transmitter module, the coupler module, the feedback receiver module, and the transmission lines) The examples shown in FIG. 8 may comprise one or more optional additional features corresponding to one or more aspects mentioned in connection with the proposed concept or one or more examples described above (e.g. FIGS. 1 to 7) or below.

Various examples relate to a machine readable storage medium including program code, when executed, to cause a machine to perform the method 800.

Various examples relate to a computer program having a program code for performing the method 800 when the computer is executed on a computer or processor.

Various examples relate to a machine readable storage including machine readable instructions, when executed, to implement a method 800 or realize an apparatus 100 or means 500 for providing control signals.

Various examples relate to tracking a TX/RX (transmitter and/receiver) antenna tuner algorithm with a self-study in the operation for mobile application. Various examples relate to an adaptive method of antenna tuning using a field sensor and tracking algorithm. There is no technical ability to improve antenna efficiency using indirect methods, such as return loss analyses, for example. Various examples and methods may use a direct power sensor of radiated power. The sensor may show conditional (not calibrated power scale) powers. Using the bigger-smaller principle the best (or improved) antenna tuner code may be found, for example. Antenna efficiency may be increased by of 2 to 6 dB depending on the antenna phase, for example. Further, the methods used show low sensitivity to tolerances of the antenna tuner and the used coupler.

There is a demand for providing an improved concept for providing a control signal for a variable impedance matching circuit, which may enable an improvement of the performance of transmitters and/or transceivers.

This demand may be satisfied by the subject matter of the claims.

In the following examples pertain to further examples. Example 1 is an apparatus for providing a control signal for a variable impedance matching circuit, comprising a control module configured to generate a control signal for adjusting an impedance of a variable impedance matching circuit coupled to an antenna module, wherein the control module is configured to generate the control signal based on a sensor signal received from a sensor circuit located in proximity to the antenna module, wherein the sensor signal comprises information related to a power of an electromagnetic signal radiated by the antenna module.

In example 2, the subject matter of example 1 can optionally include the sensor signal comprising information related to a power of a magnetic field component of the electromagnetic signal radiated by the antenna module.

In example 3, the subject matter of example 1 or 2 can optionally include the sensor circuit comprising a field probe circuit coupled to a detector circuit, wherein the detector circuit is configured to determine a root mean square power of the electromagnetic signal radiated by the antenna module and sensed by the field probe circuit.

In example 4, the subject matter of any of the previous examples can optionally include the sensor circuit comprising at least one of a magnetoresistive coil, a hall sensor circuit, a capacitive circuit, an inductive circuit, and a microstrip inductor circuit.

In example 5, the subject matter of any of the previous examples can optionally include the sensor circuit located at a distance of between 5 mm to 5 cm from the antenna module.

In example 6, the subject matter of any of the previous examples can optionally include the sensor circuit being configured to measure the power of the electromagnetic signal radiated by the antenna module at a time interval of between 10 μs to 30 μs.

In example 7, the subject matter of any of the previous examples can optionally include the variable impedance matching circuit comprising at least one adjustable impedance component, wherein the at least one adjustable impedance component comprises at least one of an adjustable capacitor circuit and an adjustable inductor circuit.

In example 8, the subject matter of any of the previous examples can optionally include a transmitter module coupled to the variable impedance matching circuit, wherein the transmitter module is configured to generate a high frequency transmit signal to be transmitted by the antenna module.

In example 9, the subject matter of any of the previous examples can optionally include a coupler module located between the transmitter module and the antenna module, wherein the coupler module is configured to provide a forward feedback signal based on the high frequency transmit signal provided by the transmitter module and a reverse feedback signal based on a reflected portion of the high frequency transmit signal received from the antenna module, wherein the control module is configured to generate the control signal based on a selection of a control code based on the forward feedback signal and the reverse feedback signal.

In example 10, the subject matter of any of the previous examples can optionally include the control module being configured to select the control code based on a voltage standing wave ratio value and a phase offset value derived from the forward feedback signal and the reverse feedback signal.

In example 11, the subject matter of any of the previous examples can optionally include the control module being configured to select a control code from a plurality of control codes stored in a memory module, wherein the plurality of control codes are arranged in one or more code sets, and wherein the control module is configured to generate the control signal based on the selected control code.

In example 12, the subject matter of any of the previous examples can optionally include the can optionally include each code set comprising a plurality of control codes comprising impedance adjustment information associated with a same predetermined voltage standing wave ratio value and a different predetermined phase offset value.

In example 13, the subject matter of example 11 or 12 can optionally include the control module being configured to select different control codes for generating the control signal at a time interval of between 10 μs to 30 μs.

In example 14, the subject matter of any of examples 11 to 13 can optionally include the at least one control code comprising impedance adjustment information for adjusting an impedance of at least one adjustable impedance component of the variable impedance matching circuit.

In example 15, the subject matter of example 14 can optionally include the impedance adjustment information comprising at least one of a capacitance value and an inductance value for adjusting the impedance of the variable impedance matching circuit.

In example 16, the subject matter of any of examples 11 to 15 can optionally include the control module being configured to select a control code as a default adjustment code and to further select a sequence of further control codes for generating a sequence of further control signals for adjusting an impedance of the variable impedance matching circuit.

In example 17, the subject matter of any of examples 11 to 16 can optionally include the control module being configured to select a further control code of the sequence of further control codes as the default control code based on the sensor signal indicating a power of an electromagnetic signal radiated by the antenna module based on the further control code.

In example 18, the subject matter of example 16 or 17 can optionally include the control module being configured to select a further control code of the sequence of further control codes as the default control code if the sensor signal indicates that an increase in power of the electromagnetic signal is produced based on the further control code.

In example 19, the subject matter of any of examples 16 to 18 can optionally include the control module being configured to select a further control code of the sequence of further control codes as the default control code if the sensor signal indicates that a largest increase in power of the electromagnetic signal is produced based on the further control code.

In example 20, the subject matter of any of examples 16 to 19 can optionally include the control module being configured to select the sequence of further control codes based on a predetermined voltage standing wave ratio value and a predetermined phase value associated with the default control code.

In example 21, the subject matter of any of examples 16 to 20 can optionally include each further control code in the sequence of further control codes comprising impedance adjustment information associated with a further predetermined voltage standing wave ratio value and a further predetermined phase value lying within a threshold range of the predetermined voltage standing wave ratio value and a predetermined phase value associated with the impedance adjustment information of the default control code.

In example 22, the subject matter of any of examples 16 to 21 can optionally include at least one further control code in the sequence of further control codes comprising impedance adjustment information associated with the same predetermined voltage standing wave ratio value or the same predetermined phase value as the default control code.

In example 23, the subject matter of any of examples 16 to 22 can optionally include one of the further predetermined voltage standing wave ratio value and the further predetermined phase value associated with a further control code in the sequence of further control codes being the same as a previous further control code in the sequence of further control codes.

In example 24, the subject matter of any of examples 11 to 22 can optionally include the control module being configured to select a control code as a default control code and to generate an adjusted control code based on an adjustment of the impedance adjustment information of the default control code, wherein the adjusted control code is used for generating a further control signal for adjusting an impedance of the variable impedance matching circuit.

In example 25, the subject matter of example 24 can optionally include the control module being configured to adjust the impedance adjustment information by varying at least one of a capacitance value and an inductance value by a predetermined adjustment value.

In example 26, the subject matter of example 24 or 25 can optionally include the control module being configured to update a code set with an adjusted control code comprising adjusted impedance information if the sensor signal indicates that an increase in power of the electromagnetic signal is produced based on the adjusted control code.

In example 27, the subject matter of any of examples 24 to 26 can optionally include the control module being configured to select an adjusted control code comprising adjusted impedance information as the default control code if the sensor signal indicates that an increase in power of the electromagnetic signal is produced based on the adjusted control code.

Example 28 is a signal generation means, comprising a means for generating a control signal configured to generate a control signal for adjusting an impedance of a variable impedance matching circuit coupled to an antenna module, wherein the means for generating a control signal is configured to generate the control signal based on a sensor signal received from a sensor circuit located in proximity to the antenna module, wherein the sensor signal comprises information related to a power of an electromagnetic signal radiated by the antenna module.

In example 29, the subject matter of example 28 can optionally include the sensor signal comprising information related to a power of a magnetic field component of the electromagnetic signal radiated by the antenna module.

In example 30, the subject matter of example 28 or 29 can optionally include the sensor circuit comprising a field probe circuit coupled to a detector circuit, wherein the detector circuit is configured to determine a root mean square power of the electromagnetic signal radiated by the antenna module and sensed by the field probe circuit.

In example 31, the subject matter of any of examples 28 to 30 can optionally include the sensor circuit comprising at least one of a magnetoresistive coil, a hall sensor circuit, a capacitive circuit, an inductive circuit, and a microstrip inductor circuit.

In example 32, the subject matter of any of examples 28 to 31 can optionally include the sensor circuit being located at a distance of between 5 mm to 5 cm from the antenna module.

Example 33 is a transmitter comprising a transmitter module coupled to a variable impedance matching circuit, wherein the transmitter module is configured to generate a high frequency transmit signal to be transmitted by an antenna module; an apparatus for providing a control signal for a variable impedance matching circuit according to any of the previous claims; and an antenna module configured to radiate an electromagnetic signal based on the high frequency transmit signal.

Example 34 is a transmitter or a transceiver comprising an apparatus for providing a control signal for a variable impedance matching circuit according to any of examples 1 to 32.

Example 35 is a mobile device comprising a transmitter or a transceiver according to example 33 or 34.

Example 36 is a cell phone comprising a transmitter or a transceiver according to example 33 or 34.

Example 37 is a method for providing a control signal for a variable impedance matching circuit, the method comprising receiving a sensor signal from a sensor circuit located in proximity to an antenna module, wherein the sensor signal comprises information related to a power of an electromagnetic signal radiated by the antenna module; and generating a control signal for adjusting an impedance of a variable impedance matching circuit coupled to the antenna module based on the sensor signal.

In example 38, the subject matter of example 37 can optionally comprise selecting a control code from a plurality of control codes stored in a memory module, wherein the plurality of control codes are arranged in one or more code sets, and generating the control signal based on the selected control code.

In example 39, the subject matter of example 37 or 38 can optionally comprise selecting different control codes for generating the control signal at a time interval of between 10 μs to 30 μs.

In example 40, the subject matter of any of examples 37 to 39 can optionally comprise selecting a control code as a default adjustment code and further selecting a sequence of further control codes for generating a sequence of further control signals for adjusting an impedance of the variable impedance matching circuit.

In example 41, the subject matter of any of examples 38 to 40 can optionally comprise selecting a further control code as the default control code based on information related to a power of an electromagnetic signal radiated by the antenna module due to a further control signal generated by the control module based on the further control code.

In example 42, the subject matter of any of examples 38 to 41 can optionally comprise selecting a further control code as the default control code if the sensor signal indicates that an increase in power of the electromagnetic signal is produced based on the further control code.

In example 43, the subject matter of any of examples 38 to 42 can optionally comprise selecting a further control code of the plurality of further control codes as the default control code if the sensor signal indicates that a largest increase in power of the electromagnetic signal is produced based on the selected further control code.

In example 44, the subject matter of any of examples 38 to 43 can optionally comprise selecting one control code as a default control code and generating an adjusted control code based on an adjustment of the impedance adjustment information of the default control code, and generating a further control signal for adjusting an impedance of the variable impedance matching circuit based on the adjusted control code.

In example 45, the subject matter of any of examples 38 to 44 can optionally comprise adjusting the impedance adjustment information by varying at least one of a capacitance value and an inductance value by a predetermined adjustment value.

In example 46, the subject matter of any of examples 38 to 45 can optionally comprise updating a code set with an adjusted control code comprising adjusted impedance information if the sensor signal indicates that an increase in power of the electromagnetic signal is produced based on the adjusted control code.

In example 47, the subject matter of any of examples 38 to 46 can optionally comprise selecting an adjusted control code comprising adjusted impedance information as the default control code if the sensor signal indicates that an increase in power of the electromagnetic signal is produced based on the adjusted control code.

Example 48 is a machine readable storage medium including program code, when executed, to cause a machine to perform the method of one of the examples 37 to 47.

Example 49 is a machine readable storage including machine readable instructions, when executed, to implement a method or realize an apparatus as claimed in any pending example.

Example 50 is a computer program having a program code for performing the method of one of the examples 37 to 47 when the computer is executed on a computer or processor.

Examples may further provide a computer program having a program code for performing one of the above methods, when the computer program is executed on a computer or processor. A person of skill in the art would readily recognize that steps of various above-described methods may be performed by programmed computers. Herein, some examples are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. The examples are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and examples of the disclosure, as well as specific examples thereof, are intended to encompass equivalents thereof.

Functional blocks denoted as “means for . . . ” (performing a certain function) shall be understood as functional blocks comprising circuitry that is configured to perform a certain function, respectively. Hence, a “means for s.th.” may as well be understood as a “means configured to or suited for s.th.”. A means configured to perform a certain function does, hence, not imply that such means necessarily is performing the function (at a given time instant).

Functions of various elements shown in the figures, including any functional blocks labeled as “means”, “means for providing a sensor signal”, “means for generating a transmit signal.”, etc., may be provided through the use of dedicated hardware, such as “a signal provider”, “a signal processing unit”, “a processor”, “a controller”, etc. as well as hardware capable of executing software in association with appropriate software. Moreover, any entity described herein as “means”, may correspond to or be implemented as “one or more modules”, “one or more devices”, “one or more units”, etc. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the Detailed Description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some examples a single act may include or may be broken into multiple sub acts. Such sub acts may be included and part of the disclosure of this single act unless explicitly excluded.

What is claimed is:

1. An apparatus for providing a control signal for a variable impedance matching circuit, comprising:
a control module configured to generate a control signal for adjusting an impedance of a variable impedance matching circuit coupled to an antenna module,
wherein the control module is configured to generate the control signal based on a sensor signal received from a sensor circuit located in proximity to the antenna module, wherein the sensor signal comprises information related to a power of an electromagnetic signal radiated by the antenna module,
wherein the control circuit is configured to select a control code from a plurality of control codes stored in a memory circuit,
wherein the plurality of control codes are arranged in one or more code sets, and
wherein the control circuit is configured to generate the control signal based on the selected control code.

2. The apparatus according to claim 1, wherein each code set comprises a plurality of control codes comprising impedance adjustment information associated with a same predetermined voltage standing wave ratio value and a different predetermined phase offset value.

3. The apparatus according to claim 1, wherein the control module is configured to select different control codes for generating the control signal at a time interval of between 10 μs to 30 μs.

4. The apparatus according to claim 1, wherein the at least one control code comprises impedance adjustment information for adjusting an impedance of at least one adjustable impedance component of the variable impedance matching circuit.

5. The apparatus according to claim 4, wherein the impedance adjustment information comprises at least one of a capacitance value and an inductance value for adjusting the impedance of the variable impedance matching circuit.

6. The apparatus according to claim 1, wherein the control module is configured to select a control code as a default adjustment code and to further select a sequence of further control codes for generating a sequence of further control signals for adjusting an impedance of the variable impedance matching circuit.

7. The apparatus according to claim 1, wherein the control module is configured to select a further control code of the sequence of further control codes as the default control code based on the sensor signal indicating a power of an electromagnetic signal radiated by the antenna module based on the further control code.

8. The apparatus according to claim 6, wherein the control module is configured to select a further control code of the sequence of further control codes as the default control code if the sensor signal indicates that an increase in power of the electromagnetic signal is produced based on the further control code.

9. The apparatus according to claim 6, wherein the control module is configured to select the sequence of further control codes based on a predetermined voltage standing wave ratio value and a predetermined phase value associated with the default control code.

10. The apparatus according to claim 6, wherein each further control code in the sequence of further control codes comprises impedance adjustment information associated with a further predetermined voltage standing wave ratio value and a further predetermined phase value lying within a threshold range of the predetermined voltage standing wave ratio value and a predetermined phase value associated with the impedance adjustment information of the default control code.

11. The apparatus according to claim 1, wherein the control module is configured to select a control code as a default control code and to generate an adjusted control code based on an adjustment of the impedance adjustment information of the default control code, wherein the adjusted control code is used for generating a further control signal for adjusting an impedance of the variable impedance matching circuit.

12. The apparatus according to claim 11, wherein the control module is configured to adjust the impedance adjustment information by varying at least one of a capacitance value and an inductance value by a predetermined adjustment value.

13. The apparatus according to claim 11, wherein the control module is configured to update a code set with an adjusted control code comprising adjusted impedance information if the sensor signal indicates that an increase in power of the electromagnetic signal is produced based on the adjusted control code.

14. The apparatus according to claim 11, wherein the control module is configured to select an adjusted control code comprising adjusted impedance information as the default control code if the sensor signal indicates that an increase in power of the electromagnetic signal is produced based on the adjusted control code.
